(19) United States
(12) Patent Application Publication
(10) Pub. No.: US 2026/0071332 A1
(43) Pub. Date: Mar. 12, 2026

(54) ETCHANT AND METHOD FOR MANUFACTURING SEMICONDUCTOR DEVICE

(71) Applicant: FUJIFILM Corporation, Tokyo (JP)

(72) Inventors: Shota OI, Shizuoka (JP); Atsushi MIZUTANI, Shizuoka (JP)

(73) Assignee: FUJIFILM Corporation, Tokyo (JP)

(21) Appl. No.: 19/390,991

(22) Filed: Nov. 17, 2025

Related U.S. Application Data
(63) Continuation of application No. PCT/JP2024/016882, filed on May 2, 2024.

(30) Foreign Application Priority Data
May 24, 2023 (JP) 2023-085670

(51) Int. Cl. C23F 1/38; H01L 21/3213

(52) U.S. Cl. CPC C23F 1/38; H10P 50/667

(57) ABSTRACT

An object is to provide an etchant which has an excellent etching rate and can suppress roughness of a surface of a molybdenum-containing substance after an etching treatment. The etchant of the present invention is an etchant used for a molybdenum-containing substance, the etchant containing a quinone compound having a quinone structure and a solvent.

### CROSS-REFERENCE TO RELATED APPLICATIONS

This application is a Continuation of PCT International Application No. PCT/JP2024/016882 filed on May 2, 2024, which claims priority under 35 U.S.C. § 119(a) to Japanese Patent Application No. 2023-085670 filed on May 24, 2023. The above applications are hereby expressly incorporated by reference, in their entirety, into the present application.

### BACKGROUND OF THE INVENTION

### 1. Field of the Invention

The present invention relates to an etchant and a method for manufacturing a semiconductor device.

### 2. Description of the Related Art

As miniaturization of electronic devices progresses, there is an increasing demand for efficiently and accurately performing an etching treatment of removing unnecessary metal-containing substances on a substrate in a manufacturing process of the electronic device.

For example, JP2022-052909A discloses an etchant for etching a two-layer film of copper and molybdenum, the etchant containing hydrogen peroxide, an acidic substance, an amine compound, a hydrogen peroxide decomposition inhibitor, and molybdenum erosion promoting ions.

### SUMMARY OF THE INVENTION

As a result of studying etching of a molybdenum-containing substance using the etchant disclosed in JP2022-052909A, the present inventors have found that it is not possible to achieve both an etching rate and suppression of roughness of a surface of the molybdenum-containing substance after the etching treatment, and there is room for further improvement in this point.

Therefore, an object of the present invention is to provide an etchant which has an excellent etching rate and can suppress roughness of a surface of a molybdenum-containing substance after an etching treatment.

Another object of the present invention is to provide a method for manufacturing a semiconductor device, using the above-described etchant.

As a result of conducting an extensive investigation to achieve the objects, the present inventors have found that the objects can be achieved by the following constitution.

[1] An etchant used for a molybdenum-containing substance, comprising:
a quinone compound having a quinone structure; and
a solvent.

[2] The etchant according to [1],
in which the solvent includes at least one selected from the group consisting of water and a water-soluble organic solvent.

[3] The etchant according to [1] or [2],
in which a content of the quinone compound is 0.0001% to 10.0% by mass with respect to a total mass of the etchant.

[4] The etchant according to any one of [1] to [3],
in which the quinone compound is a compound represented by Formula (1) described later.

[5] The etchant according to [4],
in which the quinone compound is the compound represented by Formula (1), in which R¹ and R² are not bonded to each other to form a benzene ring and R³ and R⁴ are not bonded to each other to form a benzene ring.

[6] The etchant according to any one of [1] to [5],
in which the quinone compound includes at least one selected from the group consisting of p-benzoquinone, p-chloranil, fluoranil, 2,3-dichloro-5,6-dicyano-p-benzoquinone, chloranilic acid, and tetrahydroxy-1,4-benzoquinone.

[7] The etchant according to any one of [1] to [6], further comprising:
a hydroquinone compound having a p-hydroquinone structure,
in which a content of the hydroquinone compound is 1 ppt by mass to 1 ppm by mass with respect to a total mass of the etchant.

[8] The etchant according to any one of [1] to [7],
in which a dissolved oxygen amount is 3 to 50 mg/L.

[9] The etchant according to any one of [1] to [8],
in which a relative permittivity of the solvent at 20° C. is 7 to 75. [10] The etchant according to any one of [1] to [9],
in which the solvent includes water and a water-soluble organic solvent, and a content of the water is 20% to 95% by mass with respect to a total mass of the solvent.

[11] The etchant according to any one of [1] to [10],
in which the solvent includes at least one selected from the group consisting of water, methanol, ethanol, 1-propanol, 2-propanol, dimethyl sulfoxide, sulfolane, N,N-dimethylformamide, N-methylpyrrolidone, pyridine, acetonitrile, acetone, tetrahydrofuran, and glycerin.

[12] The etchant according to any one of [1] to [11],
in which the solvent includes at least one selected from the group consisting of water, an alcohol solvent, a sulfoxide solvent, a nitrile solvent, and a sulfone solvent.

[13] The etchant according to any one of [1] to [12], further comprising: a surfactant.

[14] The etchant according to any one of [1] to [13],
in which a content of a Cr atom is 1 ppt by mass to 1 ppb by mass with respect to a total mass of the etchant.

[15] The etchant according to any one of [1] to [14],
in which a pH is 3 to 10.

[16]A method for manufacturing a semiconductor device, comprising:
a step of etching the molybdenum-containing substance using the etchant according to any one of [1] to [15].

According to the present invention, it is possible to provide an etchant which has an excellent etching rate and can suppress roughness of a surface of a molybdenum-containing substance after an etching treatment.

In addition, according to the present invention, it is possible to provide a method for manufacturing a semiconductor device, using the above-described etchant.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

In the present specification, a numerical range represented by “to” means a range including numerical values before and after “to” as a lower limit value and an upper limit value.

In the numerical range described stepwise in the present specification, the upper limit value or the lower limit value described in a certain numerical range may be replaced with the upper limit value or the lower limit value of another numerical range described stepwise. In addition, in the numerical range described in the present specification, an upper limit value and a lower limit value described in a certain numerical range may be replaced with values shown in Examples.

In the present specification, a combination of two or more preferred aspects is a more preferred aspect.

In addition, in the present specification, in a case where there are two or more components corresponding to a certain component, “content” of such a component means the total content of the two or more components.

In the present specification, in a case of a plurality of substituents, linking groups, and the like (hereinafter, referred to as a substituent and the like) represented by specific reference numeral, or in a case of simultaneously defining a plurality of the substituent and the like, it means that each of the substituent and the like may be the same as or different from each other. The same applies to the definition of the number of substituents and the like.

In the present specification, “ppm” means “parts-per-million (10⁻⁶)”, “ppb” means “parts-per-billion (10⁻⁹)”, “ppt” means “parts-per-trillion (10⁻¹²)”.

In the present specification, “A” corresponds to 0.1 nm.

### [Etchant]

Hereinafter, the etchant according to the embodiment of the present invention (hereinafter, also simply referred to as “etchant”) will be described in detail.

The etchant according to the embodiment of the present invention is an etchant used for a molybdenum-containing substance, the etchant containing a quinone compound having a quinone structure and a solvent.

The reason why the etchant having the above-described configuration can achieve the object of the present invention is not necessarily clear, but the present inventors speculate as follows.

The mechanism by which the effect is obtained is not limited by the following supposition. In other words, even in a case where an effect is obtained by a mechanism other than the following, it is included in the scope of the present invention.

In etching of the molybdenum-containing substance, depending on an oxidant, the etchant may permeate a crystal grain boundary of the molybdenum-containing substance and be removed in units of crystals, thereby causing surface roughening after the etching. In the etchant according to the present invention, the quinone compound is used as an oxidant of the molybdenum-containing substance. Since the quinone compound has a quinone structure capable of coordinating to a surface of the molybdenum-containing substance, the molybdenum-containing substance surface can be quickly oxidized, and thus the etching rate is excellent. Furthermore, by temporarily protecting an oxide layer by the coordination of the quinone compound to the surface of the molybdenum-containing substance, the etchant does not permeate the grain boundary and a uniform oxide film can be formed, and thus the roughness of the surface of the molybdenum-containing substance after etching can also be suppressed. As a result, it is considered that the etchant according to the embodiment of the present invention can achieve both the etching rate and the suppression of the roughness of the surface of the molybdenum-containing substance after etching.

The characteristic of being able to suppress the roughness of the surface of the molybdenum-containing substance after etching is simply referred to as “suppression of surface roughness”; and at least one of the etching rate or the suppression of the surface roughness is more excellent is also referred to as “effect of the present invention is more excellent”.

### [Quinone Compound]

The etchant contains a quinone compound which is a compound having a quinone structure. The quinone compound is not particularly limited as long as it has a quinone structure as an entire structure or a partial structure of the compound.

Examples of the quinone structure include a structure in which two carbon atoms in an aromatic ring are substituted with a carbonyl carbon (C═O), and a non-benzene-based quinone structure (for example, a quinone structure composed of a 7-membered ring, a 10-membered ring, a 5-membered ring, or a 12-membered ring) may be used.

The above-described aromatic ring may be any of an aromatic hydrocarbon ring or an aromatic heterocyclic ring, and an aromatic hydrocarbon ring is preferable.

The above-described aromatic ring may be a monocyclic ring or a polycyclic ring, but is preferably a monocyclic ring.

The number of carbon atoms in the above-described aromatic ring is preferably 5 to 20 and more preferably 6 to 12.

The quinone structure is preferably a benzene-based quinone structure, more preferably a benzoquinone structure, a naphthoquinone structure, or an anthraquinone structure, and still more preferably a benzoquinone structure.

A position of two carbonyl groups in the quinone structure are not particularly limited, and for example, in a case where the quinone compound has a benzoquinone structure, the benzoquinone structure may be any of a 1,2-benzoquinone structure (ortho-benzoquinone structure) or a 1,4-benzoquinone structure (para-benzoquinone structure).

Among these, in a case where the quinone compound has a benzoquinone structure, a para-benzoquinone structure is preferable.

A molecular weight of the quinone compound is not particularly limited, but is preferably 50 to 500 and more preferably 100 to 300.

The quinone compound is also preferably a compound represented by Formula (1).

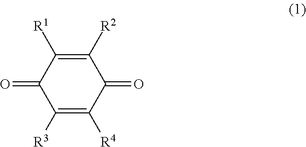

In Formula (1), R¹ to R⁴ each independently represent a hydrogen atom or a substituent.

Examples of the above-described substituent include an alkyl group, an alkenyl group, an aryl group, a hydroxy group, a carbonyl group, a cyano group, a halogen atom, an alkoxy group, an aryloxy group, an alkyloxycarbonyl group, a nitro group, a fluoroalkyl group, and an amino group.

The number of carbon atoms in the alkyl group and the alkoxy group is preferably 1 to 20, more preferably 1 to 12, and still more preferably 1 to 6.

The number of carbon atoms in the aryl group and the aryloxy group is preferably 5 to 20 and more preferably 6 to 12.

The number of carbon atoms in the alkyloxycarbonyl group is preferably 2 to 21, more preferably 2 to 13, and still more preferably 2 to 7.

Examples of the halogen atom include a fluorine atom, a chlorine atom, a bromine atom, and an iodine atom; and a fluorine atom or a chlorine atom is preferable.

The fluoroalkyl group is an alkyl group in which at least one fluorine atom is substituted, and may be a perfluoroalkyl group.

Among these, R¹ to R⁴ are preferably a hydrogen atom, an alkyl group, a hydroxy group, a cyano group, or a halogen atom.

R¹ and R² may be bonded to each other to form a benzene ring which may have a substituent, and R³ and R⁴ may be bonded to each other to form a benzene ring which may have a substituent. From the viewpoint that the effect of the present invention is more excellent, it is also preferable that R¹ and R² are not bonded to each other to form a benzene ring and R³ and R⁴ are not bonded to each other to form a benzene ring.

Examples of the substituent which may be contained in the benzene ring include the substituents exemplified as the groups represented by R¹ to R⁴ above.

Examples of the quinone compound represented by Formula (1) include p-benzoquinone, p-chloranil, p-fluoranil (fluoranil), p-bromanil (bromanil), 2,3-dichloro-5,6-dicyano-1,4-benzoquinone (DDQ), chloranilic acid, tetrahydroxy-1,4-benzoquinone (tetrahydroxybenzoquinone), ubiquinone, toluquinone, 2,6-dimethyl-1,4-benzoquinone, 2,5-dimethyl-1,4-benzoquinone, 1,4-naphthoquinone, and anthraquinone.

Examples of the quinone compound other than the above-described compounds include 1,2-benzoquinone, 3,5-di-tert-butyl-1,2-benzoquinone, o-chloranil, o-fluoranil, o-bromanil, 1,2-naphthoquinone, o-phenazene quinone, and acenaphthenequinone.

Among these, as the quinone compound, p-benzoquinone, p-chloranil, fluoranil, DDQ, chloranilic acid, tetrahydroxybenzoquinone, o-chloranil, 3,5-di-tert-butyl-1,2-benzoquinone, 1,4-naphthoquinone, or anthraquinone is preferable; p-benzoquinone, p-chloranil, fluoranil, DDQ, chloranilic acid, tetrahydroxybenzoquinone, o-chloranil, 1,4-naphthoquinone, or anthraquinone is more preferable; p-benzoquinone, p-chloranil, fluoranil, DDQ, chloranilic acid, or tetrahydroxybenzoquinone is still more preferable; and p-benzoquinone, p-chloranil, fluoranil, chloranilic acid, or tetrahydroxybenzoquinone is particularly preferable.

The quinone compound may be used alone or in combination of two or more thereof.

From the viewpoint that the effect of the present invention is more excellent, a content of the quinone compound is preferably 0.000005% to 20.0% by mass, more preferably 0.0001% to 10.0% by mass, still more preferably 0.001% to 10.0% by mass, and particularly preferably 0.01% to 1.0% by mass with respect to the total mass of the etchant.

### [Solvent]

The etchant contains a solvent.

The above-described solvent is not particularly limited as long as it can dissolve the quinone compound, and examples thereof include water, an organic solvent, and a mixture thereof, and it is preferable to contain at least one selected from the group consisting of water and a water-soluble organic solvent.

The above-described water-soluble organic solvent means an organic solvent having a solubility of 50 g/L or more in water at 25° C. The water-soluble organic solvent is preferably mixed with water at arbitrary ratio.

From the viewpoint that the effect of the present invention is more excellent, a relative permittivity of the solvent is preferably 5 to 90, more preferably 7 to 75, still more preferably 20 to 75, particularly preferably 24 to 75, and most preferably 50 to 75.

The above-described relative permittivity is preferably within the above-described range at 15° C. to 30° C., and more preferably within the above-described range at 20° C.

As the relative permittivity, a known literature value can be used. As the literature value, a value described in “Chemical Handbook: Basic Edition II, 5th Edition” (Maruzen Co., Ltd., 2004) can be used; and in a case where the value is not described in the literature, CRC Handbook of Chemistry and Physics may be referred to. In a case where there is no known literature value, a value measured by a known method can be adopted. Examples of a method for measuring the relative permittivity include a method in which 50 mL of the solvent adjusted to a predetermined temperature is prepared as a measurement sample, and an alternating current voltage at a frequency of 1 MHz is applied using E4980A Precision LCR Meter manufactured by Keysight Technologies and DPT-013-050 manufactured by Keysight Technologies as an electrode, and a method in which the measurement is performed using Model 871 manufactured by Mitsuwa Frontech.

In a case of using a mixed solvent in which two or more solvents are combined, the above-described literature value can be used as the relative permittivity. In a case where there is no literature value, a value measured by the above-described method for the mixed solvent can be adopted.

Examples of the solvent include water, an alcohol solvent, a sulfoxide solvent, a sulfone solvent, a nitrile solvent, an amide solvent, an amine solvent, a ketone solvent, an ester solvent, an ether solvent, a carboxylic acid solvent, a hydrocarbon solvent, and a halogen-based solvent.

The solvent preferably includes at least one selected from the group consisting of water, an alcohol solvent, a sulfoxide solvent, a sulfone solvent, a nitrile solvent, an amide solvent, an amine solvent, a ketone solvent, an ether solvent, an ester solvent, and a halogen-based solvent; more preferably includes at least one selected from the group consisting of water, an alcohol solvent, a sulfoxide solvent, a sulfone solvent, an amide solvent, a nitrile solvent, and a ketone solvent; still more preferably includes at least one selected from the group consisting of water, an alcohol solvent, a sulfoxide solvent, a sulfone solvent, and a nitrile solvent; and particularly preferably includes at least one selected from the group consisting of water and an alcohol solvent.

In addition, in a case where the relative permittivity of the solvent is 24 or more, as the organic solvent, an alcohol solvent, a sulfoxide solvent, a sulfone solvent, a ketone solvent, an ether solvent, an ester solvent, a nitrile solvent, or a halogen-based solvent is preferable; and an alcohol solvent, a sulfoxide solvent, a sulfone solvent, a ketone solvent, an ether solvent, or an ester solvent is more preferable.

The alcohol solvent may be any of a monoalcohol solvent having one hydroxy group or a polyol solvent having two or more hydroxy groups, but a monoalcohol solvent is preferable.

The number of carbon atoms in the alcohol solvent is preferably 1 to 12, more preferably 1 to 6, and still more preferably 1 or 2.

Examples of the monohydric alcohol solvent include methanol, ethanol, 1-propanol, 2-propanol, tert-butyl alcohol, 1-butanol, 2-butanol, isobutyl alcohol, 2-pentanol, tert-pentyl alcohol, hexanol, 3-methoxy-3-methyl-1-butanol (MMB), 3-methoxy-1-butanol, 1-methoxy-2-butanol, allyl alcohol, propargyl alcohol, 2-butenyl alcohol, 3-butenyl alcohol, 4-penten-2-ol, tetrahydrofurfuryl alcohol, furfuryl alcohol, and benzyl alcohol; and methanol, ethanol, 1-propanol, 2-propanol, tert-butyl alcohol, 1-butanol, 2-butanol, or isobutyl alcohol is preferable, and methanol or ethanol is more preferable.

Examples of the polyol solvent include glycerin, ethylene glycol, propylene glycol, diethylene glycol, dipropylene glycol, triethylene glycol, tetraethylene glycol, 2-methyl-1,3-propanediol, 1,3-propanediol, 2,2-dimethyl-1,3-propanediol, 1,4-butanediol, 1,3-butanediol, 1,2-butanediol, 2,3-butanediol, hexylene glycol, pinacol, and 1,3-cyclopentanediol.

Examples of the sulfoxide solvent include dimethyl sulfoxide (DMSO).

Examples of the sulfone solvent include sulfolane, 3-methylsulfolane, and 2,4-dimethylsulfolane.

Examples of the nitrile solvent include acetonitrile.

Examples of the amide solvent include N-methyl-2-pyrrolidone (NMP), N,N-dimethylformamide (DMF), 1-methyl-2-pyrrolidone, 2-pyrrolidinone, 1,3-dimethyl-2-imidazolidinone, F-caprolactam, formamide, N-methylformamide, acetamide, N-methylacetamide, N,N-dimethylacetamide, N-methylpropanamide, and hexamethylphosphoric triamide.

Examples of the amine solvent include pyridine, triethylamine, and diethylamine.

Examples of the ketone solvent include acetone, dimethyl ketone (propanone), cyclobutanone, cyclopentanone, cyclohexanone, methyl ethyl ketone (2-butanone), 5-hexanedione, methyl isobutyl ketone, 1,4-cyclohexanedione, 1,3-cyclohexanedione, and cyclohexanone.

Examples of the ester solvent include linear esters such as ethyl acetate, butyl acetate, ethyl lactate, methyl 3-methoxypropionate, propylene glycol monomethyl ether acetate, ethylene glycol monoacetate, diethylene glycol monoacetate, ethylene glycol monomethyl ether acetate, propylene glycol monoethyl ether acetate, ethylene glycol monoethyl ether acetate, ethylene glycol diacetate, and propylene glycol diacetate; and cyclic esters such as propylene carbonate, ethylene carbonate, and diethyl carbonate.

Examples of the ether solvent include dialkyl ethers such as diethyl ether, diisopropyl ether, dibutyl ether, tert-butyl methyl ether, and cyclohexyl methyl ether; glycol ethers such as diethylene glycol dimethyl ether, diethylene glycol diethyl ether, diethylene glycol dibutyl ether, tetraethylene glycol dimethyl ether, dipropylene glycol dimethyl ether, triethylene glycol diethyl ether, tetraethylene glycol diethyl ether, ethylene glycol dimethyl ether, triethylene glycol dimethyl ether, propylene glycol monomethyl ether, ethylene glycol monomethyl ether, ethylene glycol monoethyl ether, ethylene glycol monopropyl ether, ethylene glycol monoisopropyl ether, ethylene glycol monobutyl ether, diethylene glycol monomethyl ether, diethylene glycol monopropyl ether, diethylene glycol monobutyl ether, diethylene glycol monoethyl ether, triethylene glycol monomethyl ether, triethylene glycol monoethyl ether, and triethylene glycol monobutyl ether; and cyclic ethers such as tetrahydrofuran and 1,4-dioxane.

Examples of the carboxylic acid solvent include formic acid, acetic acid, and propionic acid.

Examples of the hydrocarbon solvent include aliphatic hydrocarbon solvents such as hexane, heptane, pentane, octane, cyclohexane, methylcyclohexane, cyclopentane, and methylcyclopentane; and aromatic hydrocarbon solvents such as toluene, xylene, and ethylbenzene.

Examples of the halogen-based solvent include chloroform, dichloromethane, tetrachloroethylene, and 1-bromopropane.

Among these, the solvent preferably includes at least one selected from the group consisting of water, methanol, ethanol, 1-propanol, 2-propanol, DMSO, sulfolane, DMF, NMP, pyridine, acetonitrile, acetone, glycerin, and THF; more preferably includes at least one selected from the group consisting of water, methanol, ethanol, 1-propanol, 2-propanol, DMSO, sulfolane, DMF, NMIP, acetonitrile, acetone, THF, and glycerin; still more preferably includes at least one selected from the group consisting of water, methanol, ethanol, DMSO, sulfolane, acetonitrile, and glycerin; and particularly preferably includes at least one selected from the group consisting of water, methanol, and ethanol.

The solvent may be used alone, or two or more types thereof may be used in combination. In a case where two or more solvents are used in combination, water and a water-soluble organic solvent may be used in combination, or two or more of the organic solvents may be used in combination.

From the viewpoint that the effect of the present invention is more excellent, a content of the solvent is preferably 60.0% by mass or more, more preferably 80.0% by mass or more, still more preferably 90.0% by mass or more, and particularly preferably 99.0% by mass or more with respect to the total mass of the etchant. The upper limit thereof is less than 100% by mass, preferably 99.999% by mass or less, more preferably 99.99% by mass or less, and still more preferably 99.97% by mass or less.

In a case where the solvent includes water and a water-soluble organic solvent, from the viewpoint that the effect of the present invention is more excellent, a content of the water is preferably 10% to 99% by mass, more preferably 20% to 95% by mass, and still more preferably 40% to 90% by mass with respect to the total mass of the solvent.

### [Surfactant]

From the viewpoint that the effect of the present invention is more excellent, the etchant preferably contains a surfactant.

The surfactant is not particularly limited as long as it is a compound having a hydrophilic group and a hydrophobic group (lipophilic group) in one molecule, and examples thereof include a nonionic surfactant, an anionic surfactant, a cationic surfactant, and an amphoteric surfactant; and a nonionic surfactant is preferable.

In many cases, the surfactant has at least one hydrophobic group selected from the group consisting of an aliphatic hydrocarbon group, an aromatic hydrocarbon group, and a group obtained by combining these groups.

In a case where the hydrophobic group includes an aromatic hydrocarbon group, the number of carbon atoms in the hydrophobic group included in the surfactant is preferably 6 or more and more preferably 10 or more. The upper limit thereof is not particularly limited, but may be 20 or less.

In a case where the hydrophobic group consists of only aliphatic hydrocarbon group, the number of carbon atoms in the hydrophobic group included in the surfactant is preferably 9 or more, more preferably 13 or more, and still more preferably 16 or more. The upper limit thereof is not particularly limited, but may be 30 or less.

The number of carbon atoms in the surfactant is preferably 10 to 100.

Examples of the nonionic surfactant include an ester-type nonionic surfactant such as sorbitan fatty acid ester and glycerin fatty acid ester; an ether-type nonionic surfactant such as polyoxyalkylene alkyl ether, polyoxyalkylene alkenyl ether, and polyoxyethylene alkylphenyl ether; an ester ether-type nonionic surfactant such as polyoxyalkylene monoalkylate, polyoxyalkylene dialkylate, and polyoxyethylene sorbitan fatty acid ester; an alkanolamine-type nonionic surfactant; an alkylamine ether-type surfactant such as polyoxyethylene alkylamine; an alkylamide ether-type surfactant such as bispolyoxyalkylene alkylamide; a polyoxyalkylene glycol-type surfactant; an oxyethylene-oxypropylene block copolymer; and an acetylenic glycol-type nonionic surfactant. Among these, a polyoxyalkylene alkyl ether, a polyoxyalkylene monoalkylate, a polyoxyalkylene dialkylate, a polyoxyalkylene glycol-type surfactant, or an acetylenic glycol-type nonionic surfactant is preferable, and an acetylenic glycol-type nonionic surfactant is more preferable.

As the nonionic surfactant, for example, a nonionic surfactant represented by Formula (S-1) is preferable.

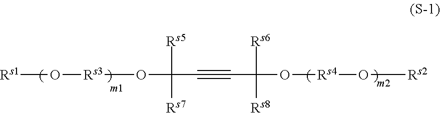

R^{s1} and R^{s2} each independently represent a hydrogen atom, an alkyl group which may have a substituent, or a phenyl group which may have a substituent.

The above-described alkyl group may be linear, branched, or cyclic, and is preferably linear.

The number of carbon atoms in the above-described alkyl group is preferably 1 to 6 and more preferably 1 to 4.

Examples of the substituent which may be included in the alkyl group and the phenyl group include an alkyl group (preferably having 1 to 3 carbon atoms), an alkoxy group (preferably having 1 to 3 carbon atoms), and a halogen atom.

R^{s1} and R^{s2} are each preferably a hydrogen atom or an alkyl group having 1 to 4 carbon atoms, and more preferably a hydrogen atom.

R^{s3} and R^{s4} each independently represent an alkylene group having 1 to 6 carbon atoms.

The above-described alkylene group having 1 to 6 carbon atoms may be linear, branched, or cyclic, and is preferably linear or branched.

The number of carbon atoms in the above-described alkylene group is preferably 1 to 4 and more preferably 2 or 3.

In a case where a plurality of R^{s3}'s and a plurality of R^{s4}'s are present, each of the plurality of R^{s3}'s and the plurality of R^{s4}'s may be the same or different from each other.

R^{s5} to R^{s8} each independently represent an alkyl group having 1 to 18 carbon atoms, which may have a substituent.

The above-described alkyl group may be linear, branched, or cyclic, and is preferably linear or branched.

The number of carbon atoms in the above-described alkyl group is preferably 1 to 12 and more preferably 1 to 6.

Examples of the substituent which may be included in the alkyl group include an alkyl group (preferably having 1 to 3 carbon atoms), an alkoxy group (preferably having 1 to 3 carbon atoms), a phenyl group, and a halogen atom.

Examples of the above-described alkyl group include a methyl group, an ethyl group, an n-butyl group, a 2-methylpropyl group, a 2-methylbutyl group, and a 2,4-dimethylpentyl group.

Among these, a linear alkyl group having 1 to 4 carbon atoms or a branched alkyl group having 3 to 6 carbon atoms is preferable as R^{s5} to R^{s8}.

m1 and m2 each independently represent an integer of 0 to 30, and are preferably an integer of 0 to 10 and more preferably an integer of 0 to 5.

m1+m2 represents an integer of 0 to 60, and is preferably an integer of 0 to 40 and more preferably an integer of 0 to 10.

It is also preferable that the nonionic surfactant represented by Formula (S-1) has a bilaterally symmetric structure. That is, it is also preferable that R^{s1} and R^{s2} are the same as each other, R^{s3} and R^{s4} are the same as each other, R^{s5} and R^{s6} are the same as each other, and R^{s7} and R^{s8} are the same as each other. In this case, m1 and m2 may be the same or different from each other, but are also preferably the same as each other.

A specific gravity of the nonionic surfactant is preferably 0.80 to 1.20 g/cm³ and more preferably 0.95 to 1.10 g/cm³.

A Hydrophile-Lipophile Balance (HLB) value of the nonionic surfactant is preferably 1 to 18 and more preferably 2 to 10. Here, the HLB value is defined with a value calculated from Griffin's formula (20×Mw/M; Mw=molecular weight of hydrophilic site, M=molecular weight of nonionic surfactant), and in some cases, a catalog value or a value calculated by another method may be used. As the HLB value is closer to 20, it is more hydrophilic, and as the HLB value is closer to 0, it is more lipophilic.

A static surface tension of a 0.1% by mass aqueous solution of the nonionic surfactant at 23° C. is preferably 10 to 55 mN/m and more preferably 25 to 40 mN/m. The above-described static surface tension can be measured by a known method.

Examples of the acetylenic glycol-type nonionic surfactant include “SURFYNOL 104 series” such as SURFYNOL 104E (2,4,7,9-tetramethyl-5-decyne-4,7-diol, specific gravity: 1.00, HLB value: 4), 104H, 104A, 104PA, and 104PG-50; “SURFYNOL 400 series” such as SURFYNOL 420, 440 (ethoxylated product of 2,4,7,9-tetramethyl-5-decyne-4,7-diol (number of moles of ethylene oxide added: 3.5), specific gravity: 0.98, HLB value: 8), 465, and 485; SURFYNOL 61, 82, 504, CT-111, CT-121, CT-131, CT-136, CT-141, CT-151, CT-171, CT-324, DF-37, DF-58, DF-75, DF-110D, DF-210, GA, OP-340, PSA-204, PSA-216, PSA-336, SE, and SE-F; and DYNOL 604 (all manufactured by Nissin Chemical Co., Ltd. and Air Products and Chemicals, Inc.).

In addition to the above, examples thereof also include OLFINE A, B, AK-02, CT-151 W, E1004, E1010, P, SPC, STG, Y, 32 W, PD-001, PD-002 W, PD-003, PD-004, EXP.4001, EXP.4036, EXP.4051, AF-103, AF-104, SK-14, and AE-3 (all manufactured by Nissin Chemical Co., Ltd.); Acetyrenol E00, E13T, E40, E60, E81, E100, E200 (all manufactured by Kawaken Fine Chemicals Co., Ltd.); and EMALEX 100, 500, 600, 700, BHA, DAPE, CS, PS, 1600, 1800, OD, and 2400 (manufactured by Nihon Emulsion Co., Ltd.).

In addition, nonionic surfactants described in [0074] to [0078] of JP2017-151432A can also be used, the content of which is incorporated herein by reference.

Examples of the anionic surfactant include a phosphoric acid ester-based surfactant having a phosphoric acid ester group, a sulfonic acid-based surfactant having a sulfo group, a phosphonic acid-based surfactant having a phosphonic acid group, a carboxylic acid-based surfactant having a carboxy group, and a sulfuric acid ester-based surfactant having a sulfuric acid ester group; and a sulfonic acid-based surfactant or a sulfuric acid ester-based surfactant is preferable.

Examples of the phosphoric acid ester-based surfactant include alkyl phosphoric acid ester, polyoxyalkylene alkyl ether phosphoric acid ester, and salts thereof.

Examples of the sulfonic acid-based surfactant include alkyl sulfonic acid, alkylbenzene sulfonic acid, alkylnaphthalene sulfonic acid, alkyl diphenyl ether disulfonic acid, alkyl methyl taurate, sulfosuccinic acid diester, polyoxyalkylene alkyl ether sulfonic acid, and salts thereof, and alkyl sulfonic acid or a salt thereof is preferable.

Examples of the phosphonic acid-based surfactant include alkylphosphonic acid, polyvinylphosphonic acid, and aminomethylphosphonic acid.

Examples of the carboxylic acid-based surfactant include alkylcarboxylic acid, alkenylcarboxylic acid, alkylbenzenecarboxylic acid, and polyoxyalkylene alkyl ether carboxylic acid, anhydrides thereof, and salts thereof.

An alkyl group contained in the above-described anionic surfactant is not particularly limited, but is preferably an alkyl group having 7 to 25 carbon atoms and more preferably an alkyl group having 8 to 17 carbon atoms.

Specific examples of the carboxylic acid-based surfactant include decanoic acid, lauric acid, myristic acid, palmitic acid, stearic acid, polyoxyethylene lauryl ether acetic acid, and polyoxyethylene tridecyl ether acetic acid.

As the anionic surfactant, for example, TAKESAAF A-24, A-21-P, A-2806-S, A-2821-S, A-2832-S, A-32-B, A-40-S, A-41-BN, A-41-C, A-41-B, A-41-S, A-43-S, A-43-NQ, A-4433, A-44-TW, A-4441, A-4442-P, A-45-K, A-51-B, A-51-G, or A-51-P (manufactured by TAKEMOTO OIL & FAT Co., Ltd.) can be used. In addition to the above, compounds described in paragraphs [0068] to [0087] of JP2023-024267A and paragraphs [0116] to [0123] of WO2022/044893A can also be used, the content of which is incorporated herein by reference.

Examples of the cationic surfactant include an aliphatic amine salt, an aliphatic quaternary ammonium salt, an alkylpyridium-based surfactant, an alkylamine acetic acid-based surfactant, and a modified aliphatic polyamine (for example, polyethylene polyamine).

Examples of the amphoteric surfactant include carboxybetaine, sulfobetaine, imidazolinium betaine, and alkylamine oxide.

Examples of the surfactant also include compounds described in paragraphs [0092] to [0096] of JP2015-158662A, paragraphs [0045] and [0046] of JP2012-151273A, and paragraphs [0014] of JP2009-147389A, the content of which is incorporated herein by reference.

From the viewpoint that the effect of the present invention is more excellent, a content of the surfactant is preferably 0.00001% to 5.0% by mass, more preferably 0.00005% to 3.0% by mass, and still more preferably 0.0005% to 0.5% by mass with respect to the total mass of the etchant.

A mass ratio of the content of the surfactant to the content of the quinone compound is preferably 0.0001 to 1,500, more preferably 0.001 to 50, and still more preferably 0.01 to 1.

### [Hydroquinone Compound]

From the viewpoint that the effect of the present invention is more excellent, it is preferable that the etchant contains a hydroquinone compound having a p-hydroquinone structure.

The hydroquinone compound is not particularly limited as long as it has a p-hydroquinone structure as an entire structure or a partial structure of the compound, and examples thereof include p-hydroquinone and a compound in which a hydrogen atom of the p-hydroquinone is substituted with a substituent. Examples of the above-described substituent include an alkyl group, an alkenyl group, an aryl group, a hydroxy group, a carbonyl group, a cyano group, a halogen atom, an alkoxy group, an aryloxy group, an alkyloxycarbonyl group, and an amino group.

The benzene ring included in the p-hydroquinone structure of the hydroquinone compound may be partially fused. For example, the hydroquinone compound may be 1,4-naphthalenediol.

As the hydroquinone compound, a compound represented by Formula (2) is preferable.

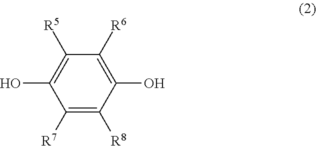

In Formula (2), R⁵ to R⁸ each independently represent a hydrogen atom or a substituent.

Examples of the above-described substituent include an alkyl group, an alkenyl group, an aryl group, a hydroxy group, a carbonyl group, a cyano group, a halogen atom, an alkoxy group, an aryloxy group, an alkyloxycarbonyl group, and an amino group; and an alkyl group, a hydroxy group, a cyano group, or a halogen atom is preferable.

The number of carbon atoms in the alkyl group and the alkoxy group is preferably 1 to 20, more preferably 1 to 12, and still more preferably 1 to 6.

The number of carbon atoms in the aryl group and the aryloxy group is preferably 5 to 20 and more preferably 6 to 12.

The number of carbon atoms in the alkyloxycarbonyl group is preferably 2 to 21, more preferably 2 to 13, and still more preferably 2 to 7.

R⁵ and R⁶ may be bonded to each other to form a benzene ring which may have a substituent, and R⁷ and R⁸ may be bonded to each other to form a benzene ring which may have a substituent. From the viewpoint that the effect of the present invention is more excellent, it is also preferable that R⁵ and R⁶ are not bonded to each other to form a benzene ring and R⁷ and R⁸ are not bonded to each other to form a benzene ring.

Examples of the substituent which may be contained in the benzene ring include the substituents exemplified as the groups represented by R⁵ to R⁸ above.

Examples of the hydroquinone compound include p-hydroquinone, p-tolylhydroquinone (methylhydroquinone), 2,6-dimethylhydroquinone, 2,3-dimethylhydroquinone, methoxyhydroquinone, chlorohydroquinone, tetrachlorohydroquinone, bromohydroquinone, tetrabromohydroquinone, tetrafluorohydroquinone, 2,3-dicyanohydroquinone, hexahydroxybenzene, 1,4-naphthalenediol, and 9,10-anthracenediol; and p-hydroquinone or methylhydroquinone is preferable.

The hydroquinone compound may be used alone or in combination of two or more thereof.

From the viewpoint that the effect of the present invention is more excellent, a content of the hydroquinone compound is preferably 0.1 ppt by mass to 5 ppm by mass, more preferably 1 ppt by mass to 1 ppm by mass, and still more preferably 0.1 to 100 ppb by mass with respect to the total mass of the etchant.

### [pH Adjuster]

The etchant may contain a pH adjuster in order to adjust and maintain a pH of the etchant.

The pH adjuster is a basic compound and an acidic compound, which are different from the above-described compounds which can be contained in the etchant (for example, the quinone compound, the surfactant, and the hydroquinone compound). However, it is permissible to adjust the pH of the etchant by adjusting the addition amount of each of the above-described components.

The basic compound is a compound which exhibits basicity (pH of more than 7.0) in an aqueous solution, and examples thereof include a basic organic compound and a basic inorganic compound.

Examples of the basic organic compound include an organic amine compound and a quaternary ammonium salt compound, and a quaternary ammonium salt compound is preferable.

Examples of the quaternary ammonium salt compound include tetraalkylammonium compounds such as tetramethylammonium hydroxide (TMAH), trimethylethylammonium hydroxide (TMEAH), dimethyldiethylammonium hydroxide (DMDEAH), methyltriethylammonium hydroxide (MTEAH), tetraethylammonium hydroxide (TEAH), tetrapropylammonium hydroxide (TPAH), and tetrabutylammonium hydroxide (TBAH); choline compounds such as 2-hydroxyethyltrimethylammonium hydroxide; and benzyltrimethylammonium hydroxide (BTMAH).

Examples of the basic inorganic compound include alkali metal hydroxides such as sodium hydroxide and potassium hydroxide, and alkaline earth metal hydroxides.

The acidic compound is a compound which exhibits acidity (a pH of less than 7.0) in an aqueous solution.

Examples of the acidic compound include an acidic inorganic compound.

Examples of the acidic inorganic compound include hydrochloric acid (hydrogen chloride), sulfuric acid, nitric acid, nitrous acid, sulfurous acid, phosphoric acid, boric acid, and hexafluorophosphoric acid.

As the acidic compound as the pH adjuster, a salt of the acidic compound may be used as long as it is an acid or an acid ion (anion) in an aqueous solution.

The pH adjuster may be used alone, or two or more types thereof may be used in combination.

A content of the pH adjuster can be selected depending on the type and amount of other components and the target pH of the etchant.

For example, the content of the pH adjuster is preferably 0.0001% to 5% by mass and more preferably 0.001% to 1% by mass with respect to the total mass of the etchant.

### [Other Components]

The etchant may contain other components in addition to the above-described components. Examples of the other components include an anticorrosion agent, a dispersant, and an antifoaming agent.

The anticorrosion agent is a compound which suppresses over-etching of the molybdenum-containing substance.

The anticorrosion agent is not particularly limited, and examples thereof include an azole compound, a pyrazine compound, a pyrimidine compound, an indole compound, an indolizine compound, an indazole compound, a quinoline compound, a pyrrole compound, and an oxazole compound; and an azole compound is preferable.

The azole compound is an aromatic compound having a hetero-5-membered ring which contains at least one nitrogen atom.

Examples of the azole compound include an imidazole compound, a pyrazole compound, a thiazole compound, a triazole compound, and a tetrazole compound.

As the azole compound, compounds described in paragraphs [0046] to [0050] of WO2021/166571A can be used, the content of which is incorporated herein by reference.

### [Properties of Etchant]

Hereinafter, properties of the etchant will be described in detail.

<pH>

The etchant may be acidic or basic.

From the viewpoint that the effect of the present invention is more excellent, the pH of the etchant is preferably 1 to 14, more preferably 2 to 11, and still more preferably 3 to 10.

The pH of the etchant can be controlled using, for example, the above-described pH adjuster.

The pH of the etchant can be measured by a method based on JIS Z 8802-1984 using a known pH meter. A measurement temperature of the pH is 25° C.

### <Dissolved Oxygen Amount>

From the viewpoint that the effect of the present invention is more excellent, a dissolved oxygen amount in the etchant is preferably 0.1 to 100 mg/L and more preferably 3 to 50 mg/L.

The dissolved oxygen amount in the etchant can be measured by a fluorescence method (for example, using a fluorescence-type dissolved oxygen measurement sensor manufactured by Hamilton).

A method of adjusting the dissolved oxygen amount in the etchant is not particularly limited, and examples thereof include a method of reducing the dissolved oxygen amount in a raw material used for preparing the etchant and/or the etchant, a method of increasing the dissolved oxygen amount, and a combination thereof. In addition, the dissolved oxygen amount in the etchant may be adjusted by preparing the etchant by combining raw materials (for example, the solvent) having an appropriate dissolved oxygen amount.

Examples of the method of reducing the dissolved oxygen amount include a bubbling method of blowing an inert gas (for example, nitrogen gas) into the raw material used for preparing the etchant and/or the etchant, and a method of degassing the etchant in a vacuum or under reduced pressure. Examples of the method of increasing the dissolved oxygen amount include a bubbling method of blowing an oxygen gas into the raw material used for preparing the etchant and/or the etchant.

From the viewpoint that the content of each component and the dissolved oxygen amount are easily adjusted, the dissolved oxygen amount is preferably adjusted by the bubbling method for the etchant.

### <Cr Atom>

The etchant may contain a Cr atom. From the viewpoint that the effect of the present invention is more excellent, a content of the Cr atom is preferably 0.1 ppt by mass to 5 ppb by mass and more preferably 1 ppt by mass to 1 ppb by mass with respect to the total mass of the etchant.

The content of the Cr atom is measured by inductively coupled plasma mass spectrometry (ICP-MS). As an apparatus of ICP-MS, for example, Agilent 8900 triple quadrupole inductively coupled plasma mass spectrometry (ICP-MS; for semiconductor analysis, Option #200) manufactured by Agilent Technologies, Inc., NexION350S manufactured by PerkinElmer, Inc., Agilent 8800 manufactured by Agilent Technologies, Inc., or the like can be used.

The Cr atom may be one that is intentionally added, one that is unavoidably contained in the raw material of the etchant, or one that is unavoidably contained in the etchant during the production, storage, and/or transport of the etchant.

A form of the Cr atom in the etchant is not particularly limited, and the Cr atom may be contained as particles containing Cr or as a Cr ion. The above-described particles containing Cr may be any of a form of a single body of Cr, an alloy of Cr, or Cr associated with an organic substance; and the Cr ion may form a salt or a complex.

A method of adjusting the content of the Cr atom is not particularly limited, and examples thereof include a method of removing the Cr atom from the etchant and/or the raw material used for preparing the etchant, a method of adding a component containing the Cr atom, and a combination thereof. As a method of removing the Cr atom, a known method may be appropriately selected according to the form of the Cr atom, and examples thereof include purification treatment such as filtration and ion exchange described later. In a case where the Cr atom is in a form of metal particles, filtration is preferable; and in a case where the Cr atom is in a form of an ion, ion exchange is preferable.

Among these, a method of performing purification treatment on the solvent used for preparing the etchant is preferable, and a method of performing the ion exchange on the solvent is more preferable.

### <Coarse Particles>

The etchant may contain coarse particles, but it is preferable that a content thereof is low.

The coarse particles mean particles having a diameter (particle size) of 0.1 m or more, in a case where a shape of the particles is regarded as a sphere.

The coarse particles contained in the etchant correspond to, for example, particles such as rubbish, dust, organic solid, and inorganic solid, which are contained as impurities in raw materials, and particles such as rubbish, dust, organic solid, and inorganic solid, which are brought in as contaminants during the preparation of the etchant, in which those particles are finally present as insoluble particles without being dissolved in the etchant.

It is more preferable that the etchant does not substantially contain the coarse particles. The fact of not substantially containing the coarse particles means that a content of particles having a particle diameter of 0.1 m or more is 10,000 or less per 1 mL of the etchant, and it is preferably 5,000 or less. The lower limit thereof is preferably 0 or more and more preferably 0.01 or more per 1 mL of the etchant.

The content of the coarse particles present in the etchant can be measured in a liquid phase by using a commercially available measuring device in a light scattering type liquid particle measuring method using a laser as a light source.

Examples of a method for removing the coarse particles include a purification treatment such as filtering, which will be described later.

### [Production Method]

The etchant can be produced by a known method.

Examples of a method of preparing the etchant include a method in which the quinone compound, the solvent, and an optional component are sequentially added, and then stirred and mixed, and the pH adjuster is added as necessary to adjust the pH of the mixed solution. In a case where the respective components are charged into a container, the respective components may be charged at once, or may be charged in a divided manner a plurality of times.

As a stirring device and a stirring method used for preparing the etchant, a known device may be used as a stirrer or a disperser. Examples of a stirrer include an industrial mixer, a portable stirrer, a mechanical stirrer, and a magnetic stirrer. Examples of the disperser include an industrial disperser, a homogenizer, an ultrasonic disperser, and a beads mill.

The mixing of the respective components in the step of preparing the etchant, a refining treatment described later, and storage of the produced etchant are preferably performed at 40° C. or lower, and more preferably performed at 30° C. or lower. The lower limit thereof is preferably 5° C. or higher and more preferably 10° C. or higher. By preparing, treating, and/or storing the etchant in the above-described temperature range, stable performance can be maintained for a long period of time.

It is preferable to subject any one or more of the raw materials for preparing the etchant to a purification treatment in advance. Examples of the purification treatment include known methods such as distillation, ion exchange, reprecipitation, and filtration (filtering).

Regarding a degree of purification, it is preferable to carry out the purification treatment until the purity of the raw material is 99% by mass or more, and it is more preferable to carry out the purification treatment until the purity of the raw material is 99.9% by mass or more. The upper limit thereof is preferably 99.9999% by mass or less.

A method of ion exchange is not particularly limited, and known methods can be used. Examples thereof include a method of bringing an ion exchange resin such as an anion exchange resin and a cation exchange resin into contact with the substance to be purified, and a method of passing the substance to be purified through a reverse osmosis membrane (RO membrane).

The filter which is used for filtering is not particularly limited as long as it has been used in application for filtering and the like in the related art. Examples thereof include filters formed of fluororesins such as polytetrafluoroethylene (PTFE) and tetrafluoroethylene perfluoroalkyl vinyl ether copolymer (PFA), polyamide-based resins such as nylon, polyarylsulfone (PAS), polyolefin resins (including those with a high density and a ultra-high molecular weight) such as polyethylene and polypropylene (PP), or the like. Among these materials, a material selected from the group consisting of polyethylene, polypropylene (including a high-density polypropylene), a fluororesin (including PTFE and PFA), and a polyamide-based resin (including nylon) is preferable; and a filter of the fluororesin is more preferable. By carrying out filtering of the raw materials using a filter formed of these materials, high-polarity foreign matters which are likely to cause defects can be more effectively removed.

The purification treatment may be performed by combining a plurality of the above-described purification methods. For example, the raw materials are subjected to primary purification by passing through an RO membrane, and then subjected to secondary purification by passing through a purification device consisting of a cation-exchange resin, an anion-exchange resin, or a mixed-bed type ion exchange resin.

In addition, the purification treatment may be performed a plurality of times.

A treatment of adjusting the dissolved oxygen amount may be performed on any one of the raw material for preparing the etchant or the etchant. A specific method of adjusting the dissolved oxygen amount is as described above.

The etchant can be stored, transported, and used by being filled in any container as long as corrosiveness or the like is not a problem.

In application for a semiconductor, the container is preferably a container which has a high degree of cleanliness inside the container and in which the elution of impurities from an interior wall of an accommodating portion of the container into each liquid is suppressed. Examples of such a container include various containers commercially available as a container for a semiconductor etchant, such as “CLEAN BOTTLE” series manufactured by AICELLO MILIM CHEMICAL Co., Ltd. and “PURE BOTTLE” manufactured by Kodama Plastics Co., Ltd., but the container is not limited thereto.

In addition, as the container, containers exemplified in paragraphs [0121] to [0124] of WO2022/004217A can also be used, the content of which is incorporated herein by reference.

The inside of these containers is preferably cleaned before filling the etchant. It is preferable that the amount of metal impurities (for example, Cr atoms) in the liquid used for cleaning is reduced. The etchant may be bottled in a container such as a gallon bottle and a coated bottle after the production, and then may be transported and stored.

In order to prevent changes in the components of the etchant during the storage, the inside of the container may be purged with an inert gas (such as nitrogen and argon) having a purity of 99.99995% by volume or more. In particular, a gas with a low moisture content is preferable. In addition, during the transportation and the storage, the temperature may be normal temperature or may be controlled in a range of −20° C. to 20° C. to prevent deterioration.

It is preferable that handlings including production of the etchant, opening and cleaning of the container, and filling of the etchant, treatment analysis, and measurements are all performed in a cleanroom. It is preferable that the clean room meets the 14644-1 cleanroom standard. It is preferable that the clean room satisfies any one of International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

### [Use Application]

The etchant is an etchant used for a molybdenum-containing substance, and is preferably used for a treatment of etching the molybdenum-containing substance in an object to be treated in the manufacture of a semiconductor device.

The object to be treated with the etchant is not particularly limited as long as it has the molybdenum-containing substance, and examples thereof include a substrate having the molybdenum-containing substance.

In a case where the substrate has the molybdenum-containing substance, a portion where the molybdenum-containing substance is present may be, for example, any of a front surface, a back surface, a side surface, and an inside of a groove of the substrate. In addition, in a case where the substrate has the molybdenum-containing substance, the molybdenum-containing substance is not only directly present on the surface of the substrate, but also present on the substrate through another layer.

The molybdenum-containing substance may be disposed only on one main surface of the substrate, or may be disposed on both main surfaces of the substrate. The molybdenum-containing substance may be disposed on the entire main surface of the substrate, or may be disposed on a part of the main surface of the substrate.

The molybdenum-containing substance is not particularly limited as long as it contains 30% by mass or more of molybdenum (molybdenum atom) with respect to the total mass of the molybdenum-containing substance, and preferably contains 50% by mass or more of molybdenum and more preferably contains 75% by mass or more of molybdenum. The upper limit thereof is not particularly limited and is, for example, 100% by mass.

Examples of a form of the above-described molybdenum-containing substance include an elemental molybdenum, an alloy of molybdenum and other metals (molybdenum alloy), and an oxide, a nitride, an oxynitride, a silicide, and a sulfide of molybdenum and other metals.

Examples of the other metals which form the alloy with molybdenum include copper (Cu), cobalt (Co), ruthenium (Ru), aluminum (Al), titanium (Ti), tantalum (Ta), Rh (rhodium), Cr (chromium), Hf (hafnium), Os (osmium), Pt (platinum), Ni (nickel), Mn (manganese), Zr (zirconium), La (lanthanum), Ir (iridium), and tungsten (W).

A content of molybdenum in the above-described molybdenum alloy is 30% by mass or more, preferably 50% by mass or more, and more preferably 75% by mass or more with respect to the total mass of the molybdenum alloy. The upper limit thereof is not particularly limited, and is, for example, less than 100% by mass.

The molybdenum-containing substance is preferably an elemental molybdenum, a molybdenum alloy, a molybdenum silicide (for example, MoSi₂), or a molybdenum sulfide (for example, MoS₂); more preferably an elemental molybdenum, a molybdenum alloy containing 50% by mass or more of molybdenum with respect to the total mass, MoSi₂, or MoS₂; and still more preferably an elemental molybdenum.

The form of the molybdenum-containing substance in the object to be treated is not particularly limited, and examples thereof include a form in which the molybdenum-containing substance is disposed in a film shape (molybdenum-containing film) and a form in which the molybdenum-containing substance is disposed in a wiring line shape (molybdenum-containing wiring line).

In a case where the molybdenum-containing substance has a film shape or a wiring line shape, a thickness thereof is not particularly limited and may be appropriately selected depending on the use. The thickness of the molybdenum-containing substance having a film shape or a wiring line shape is preferably 500 nm or less, more preferably 50 nm or less, and still more preferably 20 nm or less. The lower limit thereof is not particularly limited, but is preferably 1 nm or more.

The type of substrate in the object to be treated is not particularly limited, and examples thereof include various substrates such as a semiconductor wafer, a glass substrate for a photomask, a glass substrate for liquid crystal display, a glass substrate for plasma display, a substrate for field emission display (FED), a substrate for an optical disk, a substrate for a magnetic disk, and a substrate for a magneto-optical disk.

Examples of a material constituting the semiconductor substrate include silicon, silicon germanium, a Group III-V compound such as GaAs, and any combination of these.

The size, thickness, shape, and layer structure of the substrate are not particularly limited, and can be appropriately selected as desired.

In a case where the object to be treated is a semiconductor substrate, the semiconductor substrate may have an insulating film.

The insulating film in the object to be treated is not particularly limited, and examples thereof include an insulating film containing one or more materials selected from a group consisting of silicon nitride (SiN), silicon oxide, silicon carbide (SiC), silicon carbonitride, silicon oxycarbide (SiOC), silicon oxynitride, and tetraethoxysilane (TEOS). Among these, SiN, TEOS, SiC, or SiOC is preferable as the above-described material. In addition, the insulating film may be composed of a plurality of films.

The object to be treated may have various layers and/or structures as desired, in addition to the above. For example, in a case where the object to be treated is the substrate, the object to be treated may have a member such as a barrier layer, a metal wire, a gate electrode, a source electrode, a drain electrode, an insulating layer, a ferromagnetic layer, an integrated circuit structure, and/or a non-magnetic layer.

A method for manufacturing an object to be treated is not particularly limited.

The method is not particularly limited as long as it is a method of forming the insulating film and the molybdenum-containing substance on the substrate described above, which is usually performed in this field.

Examples of the method of forming the insulating film include a method in which the wafer constituting the semiconductor substrate is subjected to a heat treatment in the presence of oxygen gas to form a silicon oxide film, and then a gas of silane and ammonia is introduced thereto to form a silicon nitride film by a chemical vapor deposition (CVD) method.

Examples of the method of forming the molybdenum-containing substance (for example, the molybdenum-containing film) on the insulating film include a sputtering method, a physical vapor deposition (PVD) method, an atomic layer deposition (ALD) method, a chemical vapor deposition method, and a molecular beam epitaxy (MBE) method.

In addition, the above-described method may be performed through a predetermined mask to form a patterned molybdenum-containing substance on the substrate.

### [Etching Method]

It is preferable that the etchant according to the embodiment of the present invention is used in an etching treatment step of etching a molybdenum-containing substance in an object to be treated in a case of manufacturing a semiconductor device. The object to be etched is as described above.

A specific method of etching the molybdenum-containing substance using the etchant is not particularly limited, and a known method can be used; and examples thereof include a method of bringing the molybdenum-containing substance into contact with the etchant.

The contact method is not particularly limited, and examples thereof include a method of immersing the object to be treated in the etchant in a tank, a method of spraying the etchant onto the object to be treated, a method of flowing the etchant onto the object to be treated, and any combination thereof, and a method of immersing the object to be treated in the etchant is preferable.

Furthermore, in order to further enhance etching ability of the etchant, a mechanical stirring method may be used.

Examples of the mechanical stirring method include a method of circulating the etchant on the object to be treated, a method of flowing or spraying the etchant on the object to be treated, and a method of stirring the etchant with ultrasound or megasonic waves.

A contact time between the object to be treated and the etchant can be appropriately adjusted, and it is preferably 10 seconds to 20 minutes, more preferably 1 minute to 15 minutes, and still more preferably 3 minutes to 15 minutes.

A temperature of the etchant during the treatment is preferably 20° C. to 75° C. and more preferably 20° C. to 60° C.

After the etching treatment step, a step of bringing the object to be treated after the etching into contact with a rinsing liquid (hereinafter, also referred to as “rinsing step”) may be performed. By performing the rinsing step, an etching residue and/or the etchant on the object to be treated can be efficiently removed.

The rinsing step is preferably a step which is performed continuously subsequently after the etching treatment step, in which the semiconductor substrate is rinsed with a rinsing liquid. The rinsing step may be performed by the above-described mechanical stirring method.

Examples of the rinsing liquid include water (preferably, deionized water), methanol, ethanol, isopropyl alcohol (IPA), N-methylpyrrolidinone, y-butyrolactone, dimethyl sulfoxide, ethyl lactate, and propylene glycol monomethyl ether acetate. In addition, an aqueous rinsing liquid (diluted aqueous ammonium hydroxide or the like) having a pH of more than 8.0 may be used, and the solvent used in the etchant according to the embodiment of the present invention may be used.

As the method in which the rinsing liquid is brought into contact with the object to be treated, the method in which the etchant is brought into contact with the object to be treated can be similarly applied.

A contact time between the object to be treated and the rinsing liquid can be appropriately changed depending on the type and content of the component contained in the etchant and the composition of the object to be treated, but is practically preferably 10 to 120 seconds, more preferably 20 to 90 seconds, and still more preferably 30 to 60 seconds.

A drying step of drying the object to be treated may be performed after the above-described rinsing step.

Examples of the drying method include a spin drying method, a method of flowing a dry gas onto the semiconductor substrate, a method of heating the object to be treated by a heating unit such as a hot plate and an infrared lamp, a Marangoni drying method, a Rotagoni drying method, an isopropyl alcohol (IPA) drying method, and a method of combining any of these methods.

### [Method for Manufacturing Semiconductor Device]

The above-described etching treatment step can be suitably applied to a method for manufacturing a semiconductor device.

The above-described etching treatment step may be performed in combination before or after other steps performed on a substrate. The other steps may be incorporated into other steps during the execution of the above-described etching treatment step, or the above-described etching treatment step may be incorporated into the other steps.

Examples of the other steps include a step of forming each structure such as a metal wire, a gate structure, a source structure, a drain structure, an insulating film, a ferromagnetic layer, and a non-magnetic layer (for example, layer formation, etching, chemical mechanical polishing, modification, or the like), a resist forming step, an exposure step and a removal step, a heat treatment step, a cleaning step, and an examination step.

Examples of the steps other than the above-described steps also include a coating film forming step described in paragraph [0021] of JP2019-061978A and a laser irradiation step described in paragraph [0022] of JP2019-061978A, the content of which is incorporated herein by reference.

The above-described etching treatment step is preferably used for recess etching of a metal wire or a liner disposed on the substrate. As a result, a part of a metal wire can be removed to form a recess.

In addition, the above-described etching treatment step may be applied, for example, to NAND, dynamic random access memory (DRAM), static random access memory (SRAM), resistive random access memory (ReRAM), ferroelectric random access memory (FRAM (registered trademark)), magnetoresistive random access memory (MRAM), or phase change random access memory (PRAM), or applied to a logic circuit or a processor.

### EXAMPLES

Hereinafter, the present invention will be described in more detail with reference to Examples.

The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

In Examples, a pH of the composition was measured at 25° C. using a pH meter (manufactured by HORIBA, Ltd., model “F-74”) in accordance with JIS Z 8802-1984.

In addition, in production of compositions of Examples and Comparative Examples, all of handling of a container, and production, filling, storage, and analytical measurement of the compositions were performed in a clean room satisfying a level of ISO Class 2 or lower.

Each raw material used in each etchant shown below was a high-purity grade unless otherwise specified, and was further purified by distillation, ion exchange, filtration, or a combination thereof in advance.

### [Preparation of Etchant]

A solvent shown in the tables below was added to a 250 mL beaker, each component was added with the composition shown in the tables below, and the etchant of Example or Comparative Example was prepared by sufficiently stirring the mixture with a stirring rod coated with 1-inch Teflon (registered trademark). The quinone compound and the hydrogen peroxide and nitric acid used in Comparative Examples were added thereto immediately before the evaluation described later. The content of the solvent was the remainder of each component other than the solvent shown in the tables.

For each solvent, an ion exchange resin (Amberlite IR-124, manufactured by ORGANO CORPORATION) was added thereto and stirred before the mixing, and the ion exchange resin was removed by filtration.

A Cr content of each etchant was adjusted by a method of changing the stirring time after the addition of the ion exchange resin and a method of adding a chromium standard solution (Cr 1000) (manufactured by FUJIFILM Wako Pure Chemical Corporation) as a Cr atom source.

The Cr content (content of Cr atoms) of each etchant was quantified using ICP-MS (manufactured by Agilent Technologies, Inc.).

The etchants of Examples 46 to 49 were bubbled with oxygen at 0.2 L/min for 2 minutes while being stirred at 700 rpm using the above-described stirring rod immediately before the evaluation, and then bubbled with nitrogen for a predetermined time to adjust the dissolved oxygen amount.

The dissolved oxygen amount of each etchant was measured using a fluorescence-type dissolved oxygen measurement sensor (manufactured by Hamilton).
Example 46: 1 minute
Example 47: 1 minute and 30 seconds
Example 48: 5 minutes
Example 49: 10 minutes

Hereinafter, each component used in the etchant will be described.

### [Quinone Compound]

p-Benzoquinone (compound represented by Formula (1))
p-Chloranil (compound represented by Formula (1))
Fluoranil (compound represented by Formula (1))
DDQ (2,3-dichloro-5,6-dicyano-1,4-benzoquinone; compound represented by Formula (1))
Chloranilic acid (compound represented by Formula (1))
Tetrahydroxybenzoquinone (compound represented by Formula (1))
o-Chloranil
3,5-di-tert-Butyl-1,2-benzoquinone
1,4-Naphthoquinone (compound represented by Formula (1))
Anthraquinone (compound represented by Formula (1))

### [Solvent]

Water
Methanol
Ethanol
1-Propanol
2-Propanol
DMSO (dimethyl sulfoxide)
Sulfolane
DMF (N,N-dimethylformamide)
NMP (N-methyl-2-pyrrolidone)
Pyridine
Acetonitrile
Acetone
Glycerin
THF (tetrahydrofuran)
Toluene

### [Surfactant]

SURFYNOL 440 (nonionic surfactant, manufactured by Nissin Chemical Co., Ltd.)
SURFYNOL 104E (nonionic surfactant, manufactured by Nissin Chemical Co., Ltd.)
Decanoic acid (anionic surfactant)

### [Hydroquinone Compound]

Hydroquinone
1,4-Naphthalenediol
Methylhydroquinone

### [Other Additives]

Hydrogen chloride (pH adjuster)
TMAH (tetramethylammonium hydroxide; pH adjuster)
Hydrogen peroxide (oxidant)
Nitric acid (oxidant)

### [Evaluation]

As a molybdenum-containing substance, a substrate for evaluation was prepared by forming a metal molybdenum layer on one surface of a 12-inch silicon wafer by a PVD method, and cutting the metal molybdenum layer into 2×2 cm squares. A thickness of the above-described metal molybdenum layer was 25 nm.

An etching rate and surface roughness were evaluated by the following method using the etchant of each of Examples and Comparative Examples adjusted by the above-described method, and the above-described substrate for evaluation.

### [Etching Rate]

The above-described substrate for evaluation was immersed in the etchant of each of Examples and Comparative Examples adjusted to 25° C. for 10 minutes. Thereafter, the substrate was washed with running water at 500 mL/min for 30 seconds, and then dried using a nitrogen gun, and thus a substrate subjected to an etching treatment was obtained.

A thickness of the metal molybdenum layer before and after the etching was measured using a thin film evaluation X-ray fluorescence (XRF) analyzer (manufactured by Rigaku Corporation, AZX-400). An etching amount was calculated from a difference in thickness before and after the etching, and the etching amount was divided by a treatment time to calculate the etching rate (A/min).

The etching rate was evaluated according to the following evaluation standard. It is preferable that the etching rate is rated as 2 or higher.

5: 100/min or more
4: 50/min or more and less than 100/min
3: 30/min or more and less than 50/min
2: 10/min or more and less than 30/min
1: less than 10/min

### [Surface Roughness]

The surface of the molybdenum layer of the substrate after the etching treatment, obtained in the evaluation of the etching rate described above, was observed using an atomic force microscope (AFM; AFM Dimension Icon, manufactured by Bruker Corporation) to obtain a surface roughness Ra. The obtained surface roughness Ra was evaluated for suppression of surface roughness. It is preferable that the surface roughness is rated as 2 or higher.

5: surface roughness Ra was 0.5 nm or less.
4: surface roughness Ra was more than 0.5 nm and 1.0 nm or less.
3: surface roughness Ra was more than 1.0 nm and 1.5 nm or less.
2: surface roughness Ra was more than 1.5 nm and 2.0 nm or less.
1: surface roughness Ra was more than 2.0 nm.

### Result

The following tables show the compositions and evaluation results of each etchant.

In the tables, the content of the solvent is the remainder of the components shown in the tables.

In the tables, in a case where two or more components are used, a mixing ratio of each component described in the tables is a mass ratio. For example, in a case where “water/ethanol (8/2)” is described in the column of the solvent, it indicates that a mixed solvent of water/ethanol=8/2 (mass ratio) was used as the solvent.

In the tables, the relative permittivity of the solvent is a value at 20° C.

In the tables, “ppb” in the content indicates ppb by mass.

Table 2 is a continuation of Table 1, and Table 4 is a continuation of Table 3.

TABLE 1

| | Quinone compound (oxidant) | | Solvent | | Surfactant | |
|---|---|---|---|---|---|---|
| | | Amount | | Relative | | Amount |
| | Type | [% by mass] | Type | permittivity | Type | [% by mass] |
| Example 1 | p-Benzoquinone | 0.04 | Water/ethanol (8/2) | 69 | SURFYNOL 440 | 0.01 |
| Example 2 | p-Chloranil | 0.04 | Water/THF (6/4) | 52 | SURFYNOL 440 | 0.01 |
| Example 3 | Fluoranil | 0.04 | Water/THF (6/4) | 52 | SURFYNOL 440 | 0.01 |
| Example 4 | DDQ | 0.04 | Water/ethanol (8/2) | 69 | SURFYNOL 440 | 0.01 |
| Example 5 | Chloranilic acid | 0.04 | Water/ethanol (8/2) | 69 | SURFYNOL 440 | 0.01 |
| Example 6 | Tetrahydroxybenzoquinone | 0.04 | Water/ethanol (8/2) | 69 | SURFYNOL 440 | 0.01 |
| Example 7 | p-Benzoquinone | 0.00001 | Water/ethanol (8/2) | 69 | SURFYNOL 440 | 0.01 |
| Example 8 | p-Benzoquinone | 0.0003 | Water/ethanol (8/2) | 69 | SURFYNOL 440 | 0.01 |
| Example 9 | p-Benzoquinone | 0.5 | Water/ethanol (8/2) | 69 | SURFYNOL 440 | 0.01 |
| Example 10 | p-Benzoquinone | 0.00001 | Acetone | 22 | SURFYNOL 440 | 0.01 |
| Example 11 | p-Benzoquinone | 0.0003 | Acetone | 22 | SURFYNOL 440 | 0.01 |
| Example 12 | p-Benzoquinone | 8 | Acetone | 22 | SURFYNOL 440 | 0.01 |
| Example 13 | p-Benzoquinone | 15 | Acetone | 22 | SURFYNOL 440 | 0.01 |
| Example 14 | o-Chloranil | 0.04 | Water/ethanol (8/2) | 69 | SURFYNOL 440 | 0.01 |
| Example 15 | 3,5-di-tert-Butyl-1,2-benzoquinone | 0.04 | Water/ethanol (8/2) | 69 | SURFYNOL 440 | 0.01 |
| Example 16 | 1,4-Naphthoquinone | 0.0003 | Water/ethanol (8/2) | 69 | SURFYNOL 440 | 0.01 |
| Example 17 | 1,4-Naphthoquinone | 0.04 | Acetone | 22 | SURFYNOL 440 | 0.01 |
| Example 18 | Anthraquinone | 0.04 | Acetone | 22 | SURFYNOL 440 | 0.01 |
| Example 19 | p-Benzoquinone/chloranilic acid (1/1) | 0.04 | Water/ethanol (8/2) | 69 | SURFYNOL 440 | 0.01 |
| Example 20 | p-Benzoquinone | 0.04 | Water | 80 | SURFYNOL 440 | 0.01 |
| Example 21 | p-Benzoquinone | 0.04 | Water/ethanol (9/1) | 75 | SURFYNOL 440 | 0.01 |
| Example 22 | p-Benzoquinone | 0.04 | Water/ethanol (3/7) | 39 | SURFYNOL 440 | 0.01 |
| Example 23 | p-Benzoquinone | 0.04 | Water/ethanol (1/9) | 29 | SURFYNOL 440 | 0.01 |
| Example 24 | p-Benzoquinone | 0.04 | Water/THF (6/4) | 52 | SURFYNOL 440 | 0.01 |
| Example 25 | p-Benzoquinone | 0.04 | Water/ethanol/acetone (8/1/1) | 68 | SURFYNOL 440 | 0.01 |
| Example 26 | p-Benzoquinone | 0.04 | Methanol | 33 | SURFYNOL 440 | 0.01 |
| Example 27 | p-Benzoquinone | 0.04 | Ethanol | 25 | SURFYNOL 440 | 0.01 |
| Example 28 | p-Benzoquinone | 0.04 | 1-Propanol | 22 | SURFYNOL 440 | 0.01 |
| Example 29 | p-Benzoquinone | 0.04 | 2-Propanol | 22 | SURFYNOL 440 | 0.01 |
| Example 30 | p-Benzoquinone | 0.04 | DMSO | 48 | SURFYNOL 440 | 0.01 |
| Example 31 | p-Benzoquinone | 0.04 | Sulfolane | 47 | SURFYNOL 440 | 0.01 |
| Example 32 | p-Benzoquinone | 0.04 | DMF | 38 | SURFYNOL 440 | 0.01 |
| Example 33 | p-Benzoquinone | 0.04 | NMP | 34 | SURFYNOL 440 | 0.01 |
| Example 34 | p-Benzoquinone | 0.04 | Pyridine | 15 | SURFYNOL 440 | 0.01 |
| Example 35 | p-Benzoquinone | 0.04 | Acetonitrile | 38 | SURFYNOL 440 | 0.01 |
| Example 36 | p-Benzoquinone | 0.04 | Acetone | 22 | SURFYNOL 440 | 0.01 |
| Example 37 | p-Benzoquinone | 0.04 | Glycerin | 44 | SURFYNOL 440 | 0.01 |
| Example 38 | p-Benzoquinone | 0.04 | THF | 9 | SURFYNOL 440 | 0.01 |

TABLE 2

| | Hydroquinone compound | | pH Adjuster | | | | Cr | | |
|---|---|---|---|---|---|---|---|---|---|
| | | Amount | | Amount | | Dissolved oxygen | Amount | Etching | Surface |
| | Type | [ppb] | Type | [% by mass] | pH | amount [mg/L] | [ppb] | rate | roughness |
| Example 1 | Hydroquinone | 1 | — | — | 5 | 9 | 0.5 | 5 | 5 |
| Example 2 | Hydroquinone | 1 | — | — | 5 | 9 | 0.5 | 5 | 5 |
| Example 3 | Hydroquinone | 1 | — | — | 5 | 9 | 0.5 | 5 | 5 |
| Example 4 | Hydroquinone | 1 | — | — | 5 | 9 | 0.5 | 5 | 4 |
| Example 5 | Hydroquinone | 1 | — | — | 4 | 9 | 0.5 | 5 | 5 |
| Example 6 | Hydroquinone | 1 | — | — | 5 | 9 | 0.5 | 5 | 5 |
| Example 7 | Hydroquinone | 1 | — | — | 7 | 9 | 0.5 | 3 | 5 |
| Example 8 | Hydroquinone | 1 | — | — | 6 | 9 | 0.5 | 4 | 5 |
| Example 9 | Hydroquinone | 1 | — | — | 4 | 9 | 0.5 | 5 | 5 |
| Example 10 | Hydroquinone | 1 | — | — | 4 | 9 | 0.5 | 2 | 3 |
| Example 11 | Hydroquinone | 1 | — | — | 4 | 9 | 0.5 | 3 | 3 |
| Example 12 | Hydroquinone | 1 | — | — | 4 | 9 | 0.5 | 3 | 3 |
| Example 13 | Hydroquinone | 1 | — | — | 4 | 9 | 0.5 | 3 | 2 |
| Example 14 | Hydroquinone | 1 | — | — | 5 | 9 | 0.5 | 5 | 3 |
| Example 15 | Hydroquinone | 1 | — | — | 5 | 9 | 0.5 | 4 | 3 |
| Example 16 | Hydroquinone | 1 | — | — | 6 | 9 | 0.5 | 4 | 4 |
| Example 17 | Hydroquinone | 1 | — | — | 6 | 9 | 0.5 | 2 | 2 |
| Example 18 | Hydroquinone | 1 | — | — | 6 | 9 | 0.5 | 2 | 2 |
| Example 19 | Hydroquinone | 1 | — | — | 5 | 9 | 0.5 | 5 | 5 |
| Example 20 | Hydroquinone | 1 | — | — | 5 | 8 | 0.5 | 5 | 4 |
| Example 21 | Hydroquinone | 1 | — | — | 5 | 9 | 0.5 | 5 | 5 |
| Example 22 | Hydroquinone | 1 | — | — | 5 | 19 | 0.5 | 4 | 5 |
| Example 23 | Hydroquinone | 1 | — | — | 5 | 32 | 0.5 | 4 | 4 |
| Example 24 | Hydroquinone | 1 | — | — | 5 | 10 | 0.5 | 5 | 5 |
| Example 25 | Hydroquinone | 1 | — | — | 5 | 10 | 0.5 | 5 | 5 |
| Example 26 | Hydroquinone | 1 | — | — | — | 34 | 0.5 | 3 | 4 |
| Example 27 | Hydroquinone | 1 | — | — | — | 32 | 0.5 | 3 | 4 |
| Example 28 | Hydroquinone | 1 | — | — | — | 43 | 0.5 | 3 | 3 |
| Example 29 | Hydroquinone | 1 | — | — | — | 38 | 0.5 | 3 | 3 |
| Example 30 | Hydroquinone | 1 | — | — | — | 23 | 0.5 | 3 | 4 |
| Example 31 | Hydroquinone | 1 | — | — | — | 23 | 0.5 | 3 | 4 |
| Example 32 | Hydroquinone | 1 | — | — | — | 33 | 0.5 | 3 | 3 |
| Example 33 | Hydroquinone | 1 | — | — | — | 43 | 0.5 | 3 | 3 |
| Example 34 | Hydroquinone | 1 | — | — | — | 23 | 0.5 | 3 | 2 |
| Example 35 | Hydroquinone | 1 | — | — | — | 20 | 0.5 | 3 | 4 |
| Example 36 | Hydroquinone | 1 | — | — | — | 34 | 0.5 | 3 | 3 |
| Example 37 | Hydroquinone | 1 | — | — | — | 22 | 0.5 | 3 | 4 |
| Example 38 | Hydroquinone | 1 | — | — | — | 18 | 0.5 | 2 | 3 |

TABLE 3

| | Quinone compound (oxidant) | | Solvent | | Surfactant | |
|---|---|---|---|---|---|---|
| | | Amount | | Relative | | Amount |
| | Type | [% by mass] | Type | permittivity | Type | [% by mass] |
| Example 39 | p-Benzoquinone | 0.04 | Water/ethanol (8/2) | 69 | SURFYNOL 440 | 0.0001 |
| Example 40 | p-Benzoquinone | 0.04 | Water/ethanol (8/2) | 69 | SURFYNOL 440 | 0.001 |
| Example 41 | p-Benzoquinone | 0.04 | Water/ethanol (8/2) | 69 | SURFYNOL 440 | 0.1 |
| Example 42 | p-Benzoquinone | 0.04 | Water/ethanol (8/2) | 69 | SURFYNOL 440 | 1.0 |
| Example 43 | p-Benzoquinone | 0.04 | Water/ethanol (8/2) | 69 | SURFYNOL 104E | 0.01 |
| Example 44 | p-Benzoquinone | 0.04 | Water/ethanol (8/2) | 69 | Decanoic acid | 0.01 |
| Example 45 | p-Benzoquinone | 0.04 | Water/ethanol (8/2) | 69 | — | — |
| Example 46 | p-Benzoquinone | 0.04 | Ethanol | 25 | SURFYNOL 440 | 0.01 |
| Example 47 | p-Benzoquinone | 0.04 | Ethanol | 25 | SURFYNOL 440 | 0.01 |
| Example 48 | p-Benzoquinone | 0.04 | Ethanol | 25 | SURFYNOL 440 | 0.01 |
| Example 49 | p-Benzoquinone | 0.04 | Ethanol | 25 | SURFYNOL 440 | 0.01 |
| Example 50 | p-Benzoquinone | 0.04 | Water/ethanol (8/2) | 69 | SURFYNOL 440 | 0.01 |
| Example 51 | p-Benzoquinone | 0.04 | Water/ethanol (8/2) | 69 | SURFYNOL 440 | 0.01 |
| Example 52 | p-Benzoquinone | 0.04 | Water/ethanol (8/2) | 69 | SURFYNOL 440 | 0.01 |
| Example 53 | p-Benzoquinone | 0.04 | Water/ethanol (8/2) | 69 | SURFYNOL 440 | 0.01 |
| Example 54 | p-Benzoquinone | 0.04 | Water/ethanol (8/2) | 69 | SURFYNOL 440 | 0.01 |
| Example 55 | p-Benzoquinone | 0.04 | Water/ethanol (8/2) | 69 | SURFYNOL 440 | 0.01 |
| Example 56 | p-Benzoquinone | 0.04 | Water/ethanol (8/2) | 69 | SURFYNOL 440 | 0.01 |
| Example 57 | p-Benzoquinone | 0.04 | Water/ethanol (8/2) | 69 | SURFYNOL 440 | 0.01 |
| Example 58 | p-Benzoquinone | 0.04 | Water/ethanol (8/2) | 69 | SURFYNOL 440 | 0.01 |
| Example 59 | p-Benzoquinone | 0.04 | Water/ethanol (8/2) | 69 | SURFYNOL 440 | 0.01 |
| Example 60 | p-Benzoquinone | 0.04 | Water/ethanol (8/2) | 69 | SURFYNOL 440 | 0.01 |
| Example 61 | p-Benzoquinone | 0.04 | Water/ethanol (8/2) | 69 | SURFYNOL 440 | 0.01 |
| Example 62 | p-Benzoquinone | 0.04 | Water | 80 | — | — |
| Example 63 | p-Benzoquinone | 0.04 | Toluene | 4 | SURFYNOL 440 | 0.01 |
| Comparative | Hydrogen | 0.04 | Water | 80 | SURFYNOL 440 | 0.01 |
| Example 1 | peroxide | | | | | |
| Comparative | Nitric acid | 0.04 | Water | 80 | SURFYNOL 440 | 0.01 |
| Example 2 | | | | | | |

TABLE 4

| | | | pH Adjuster | | | Dissolved | | | |
|---|---|---|---|---|---|---|---|---|---|
| | Hydroquinone compound | | | Amount | | oxygen | Cr | | |
| | | Amount | | [% by | | amount | Amount | Etching | Surface |
| | Type | [ppb] | Type | mass] | pH | [mg/L] | [ppb] | rate | roughness |
| Example 39 | Hydroquinone | 1 | — | — | 5 | 9 | 0.5 | 5 | 4 |
| Example 40 | Hydroquinone | 1 | — | — | 5 | 9 | 0.5 | 5 | 5 |
| Example 41 | Hydroquinone | 1 | — | — | 5 | 9 | 0.5 | 5 | 5 |
| Example 42 | Hydroquinone | 1 | — | — | 5 | 9 | 0.5 | 4 | 4 |
| Example 43 | Hydroquinone | 1 | — | — | 5 | 9 | 0.5 | 5 | 5 |
| Example 44 | Hydroquinone | 1 | — | — | 5 | 9 | 0.5 | 4 | 4 |
| Example 45 | Hydroquinone | 1 | — | — | 5 | 9 | 0.5 | 4 | 3 |
| Example 46 | Hydroquinone | 1 | — | — | — | 55 | 0.5 | 3 | 3 |
| Example 47 | Hydroquinone | 1 | — | — | — | 45 | 0.5 | 3 | 4 |
| Example 48 | Hydroquinone | 1 | — | — | — | 5 | 0.5 | 3 | 4 |
| Example 49 | Hydroquinone | 1 | — | — | — | 1 | 0.5 | 2 | 4 |
| Example 50 | Hydroquinone | 1 | — | — | 5 | 9 | 2.0 | 4 | 4 |
| Example 51 | Hydroquinone | 1 | — | — | 5 | 9 | 0.0001 | 4 | 4 |
| Example 52 | Hydroquinone | 1 | Hydrogen | 4 | 2 | 9 | 0.5 | 4 | 4 |
| | | | chloride | | | | | | |
| Example 53 | Hydroquinone | 1 | Hydrogen | 0.04 | 4 | 9 | 0.5 | 5 | 5 |
| | | | chloride | | | | | | |
| Example 54 | Hydroquinone | 1 | TMAH | 0.003 | 10 | 9 | 0.5 | 5 | 5 |
| Example 55 | Hydroquinone | 1 | TMAH | 0.03 | 11 | 9 | 0.5 | 5 | 4 |
| Example 56 | 1,4-Naphthalenediol | 1 | — | — | 5 | 9 | 0.5 | 5 | 4 |
| Example 57 | Methylhydroquinone | 1 | — | — | 5 | 9 | 0.5 | 5 | 5 |
| Example 58 | — | — | — | — | 5 | 9 | 0.5 | 4 | 4 |
| Example 59 | Hydroquinone | 0.001 | — | — | 5 | 9 | 0.5 | 5 | 5 |
| Example 60 | Hydroquinone | 800 | — | — | 5 | 9 | 0.5 | 5 | 5 |
| Example 61 | Hydroquinone | 1500 | — | — | 5 | 9 | 0.5 | 4 | 4 |
| Example 62 | — | — | — | — | 5 | 9 | 0.5 | 3 | 2 |
| Example 63 | Hydroquinone | 1 | — | — | — | 35 | 0.5 | 2 | 2 |
| Comparative | Hydroquinone | 1 | — | — | 7 | 8 | 0.5 | 2 | 1 |
| Example 1 | | | | | | | | | |
| Comparative | Hydroquinone | 1 | — | — | 2 | 8 | 0.5 | 2 | 1 |
| Example 2 | | | | | | | | | |

From the results shown in the above tables, it was found that the etchant according to the embodiment of the present invention had an excellent etching rate and could suppress surface roughness.

From the comparison of Examples 1 to 6, Examples 14 to 15, Examples 17 to 19, and Example 36, it was found that the effect of the present invention was more excellent in a case where the quinone compound included at least one selected from the group consisting of p-benzoquinone, p-chloranil, fluoranil, 2,3-dichloro-5,6-dicyano-p-benzoquinone, chloranilic acid, and tetrahydroxy-1,4-benzoquinone; and the effect of the present invention was further excellent in a case where the quinone compound included at least one selected from the group consisting of p-benzoquinone, p-chloranil, fluoranil, chloranilic acid, and tetrahydroxy-1,4-benzoquinone.

From the comparison of Examples 1 to 6, Examples 14 to 15, Examples 17 to 19, and Example 36, it was found that the effect of the present invention was more excellent in a case where the quinone compound was the compound represented by Formula (1); and the effect of the present invention was further excellent in a case where the quinone compound was the compound represented by Formula (1) in which R¹ and R² did not bond to each other to form a benzene ring and R³ and R⁴ did not bond to each other to form a benzene ring.

From the comparison of Example 1 and Examples 7 to 9 and the comparison of Examples 10 to 13 and Example 36, it was found that the etching rate was more excellent in a case where the content of the quinone compound was 0.0001% by mass or more with respect to the total mass of the etchant; the etching rate was further excellent in a case where the content of the quinone compound was 0.001% by mass or more; the etching rate was particularly excellent in a case where the content of the quinone compound was 0.01% by mass or more; and the surface roughness could be further suppressed in a case where the content of the quinone compound was 10.0% by mass or less.

From the comparison of Examples 20 to 38 and Example 63, it was found that the effect of the present invention was more excellent in a case where the solvent included at least one selected from the group consisting of water and a water-soluble organic solvent; and the effect of the present invention was further excellent in a case where the solvent included at least one selected from the group consisting of water, an alcohol solvent, a sulfoxide solvent, a nitrile solvent, and a sulfone solvent.

From the comparison of Examples 20 to 38 and Example 63, it was found that the effect of the present invention was more excellent in a case where the solvent included at least one selected from the group consisting of water, methanol, ethanol, 1-propanol, 2-propanol, dimethyl sulfoxide, sulfolane, N,N-dimethylformamide, N-methylpyrrolidone, pyridine, acetonitrile, acetone, tetrahydrofuran, and glycerin; and the surface roughness could be further suppressed in a case where the solvent included at least one selected from the group consisting of water, methanol, ethanol, dimethyl sulfoxide, sulfolane, and acetonitrile.

From the comparison of Examples 20 to 38 and Example 63, it was found that the effect of the present invention was more excellent in a case where the relative permittivity of the solvent at 20° C. was 7 or more; the effect of the present invention was further excellent in a case where the relative permittivity of the solvent at 20° C. was 20 or more; and the effect of the present invention was particularly excellent in a case where the relative permittivity of the solvent at 20° C. was 50 or more. In addition, it was found that the surface roughness could be further suppressed in a case where the relative permittivity of the solvent at 20° C. was 75 or less.

From the comparison of Example 1 and Examples 20 to 25, it was found that, in a case where the solvent included water and a water-soluble organic solvent, the effect of the present invention was more excellent in a case where the content of the water was 20% to 95% by mass with respect to the total mass of the solvent.

From the comparison of Example 1 and Examples 39 to 42, it was found that the effect of the present invention was more excellent in a case where the content of the surfactant was 0.0005% to 0.5% by mass with respect to the total mass of the etchant.

From the comparison of Example 1 and Examples 43 to 45, it was found that the surface roughness could be further suppressed in a case where the etchant contained the surfactant; and the effect of the present invention was more excellent in a case where the surfactant was a nonionic surfactant.

From the comparison of Example 27 and Examples 46 to 49, it was found that the etching rate was more excellent in a case where the dissolved oxygen amount was 3 mg/L or more; and the surface roughness could be further suppressed in a case where the dissolved oxygen amount was 50 mg/L or less.

From the comparison of Example 1 and Examples 50 and 51, it was found that the effect of the present invention was more excellent in a case where the content of the Cr atom was 1 ppt by mass to 1 ppb by mass with respect to the total mass of the etchant.

From the comparison of Example 1 and Examples 52 to 55, it was found that the effect of the present invention was more excellent in a case where the pH was 3 to 10.

From the comparison of Example 1 and Examples 56 to 58, it was found that the effect of the present invention was more excellent in a case where the etchant contained the hydroquinone compound.

From the comparison of Example 1 and Examples 59 to 61, it was found that the effect of the present invention was more excellent in a case where the content of the hydroquinone compound was 1 ppt by mass to 1 ppm by mass with respect to the total mass of the etchant.

What is claimed is:

1. An etchant used for a molybdenum-containing substance, comprising:
a quinone compound having a quinone structure; and
a solvent.

2. The etchant according to claim 1,
wherein the solvent includes at least one selected from the group consisting of water and a water-soluble organic solvent.

3. The etchant according to claim 1,
wherein a content of the quinone compound is 0.0001% to 10.0% by mass with respect to a total mass of the etchant.

4. The etchant according to claim 1,
wherein the quinone compound is a compound represented by Formula (1), 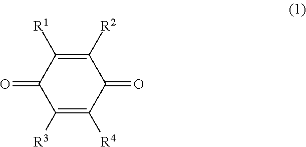
in Formula (1), R¹ to R⁴ each independently represent a hydrogen atom or a substituent, and
R¹ and R² may be bonded to each other to form a benzene ring which may have a substituent, and R³ and R⁴ may be bonded to each other to form a benzene ring which may have a substituent.

5. The etchant according to claim 4,
wherein the quinone compound is the compound represented by Formula (1), in which R¹ and R² are not bonded to each other to form a benzene ring and R³ and R⁴ are not bonded to each other to form a benzene ring.

6. The etchant according to claim 1,
wherein the quinone compound includes at least one selected from the group consisting of p-benzoquinone, p-chloranil, fluoranil, 2,3-dichloro-5,6-dicyano-p-benzoquinone, chloranilic acid, and tetrahydroxy-1,4-benzoquinone.

7. The etchant according to claim 1, further comprising:
a hydroquinone compound having a p-hydroquinone structure,
wherein a content of the hydroquinone compound is 1 ppt by mass to 1 ppm by mass with respect to a total mass of the etchant.

8. The etchant according to claim 1,
wherein a dissolved oxygen amount is 3 to 50 mg/L.

9. The etchant according to claim 1,
wherein a relative permittivity of the solvent at 20° C. is 7 to 75.

10. The etchant according to claim 1,
wherein the solvent includes water and a water-soluble organic solvent, and
a content of the water is 20% to 95% by mass with respect to a total mass of the solvent.

11. The etchant according to claim 1,
wherein the solvent includes at least one selected from the group consisting of water, methanol, ethanol, 1-propanol, 2-propanol, dimethyl sulfoxide, sulfolane, N,N-dimethylformamide, N-methylpyrrolidone, pyridine, acetonitrile, acetone, tetrahydrofuran, and glycerin.

12. The etchant according to claim 1,
wherein the solvent includes at least one selected from the group consisting of water, an alcohol solvent, a sulfoxide solvent, a nitrile solvent, and a sulfone solvent.

13. The etchant according to claim 1, further comprising:
a surfactant.

14. The etchant according to claim 1,
wherein a content of a Cr atom is 1 ppt by mass to 1 ppb by mass with respect to a total mass of the etchant.

15. The etchant according to claim 1,
wherein a pH is 3 to 10.

16. A method for manufacturing a semiconductor device, comprising:
a step of etching the molybdenum-containing substance using the etchant according to claim 1.

17. The etchant according to claim 2,
wherein a content of the quinone compound is 0.0001% to 10.0% by mass with respect to a total mass of the etchant.

18. The etchant according to claim 2,
wherein the quinone compound is a compound represented by Formula (1), 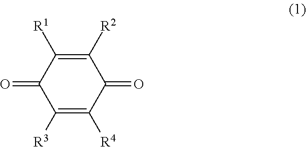
in Formula (1), R¹ to R⁴ each independently represent a hydrogen atom or a substituent, and
R¹ and R² may be bonded to each other to form a benzene ring which may have a substituent, and R³ and R⁴ may be bonded to each other to form a benzene ring which may have a substituent.

19. The etchant according to claim 18,
wherein the quinone compound is the compound represented by Formula (1), in which R¹ and R² are not bonded to each other to form a benzene ring and R³ and R⁴ are not bonded to each other to form a benzene ring.

20. The etchant according to claim 2,
wherein the quinone compound includes at least one selected from the group consisting of p-benzoquinone, p-chloranil, fluoranil, 2,3-dichloro-5,6-dicyano-p-benzoquinone, chloranilic acid, and tetrahydroxy-1,4-benzoquinone.
